(19) United States
(12) Patent Application Publication
(10) Pub. No.: US 2009/0068599 A1
(43) Pub. Date: Mar. 12, 2009

(54) METHOD OF MANUFACTURING IMAGE SENSOR

(76) Inventor: Do Young Lee, Seongnam-Si (KR)

Correspondence Address: IPLA P.A., 3580 WILSHIRE BLVD., 17TH FLOOR, LOS ANGELES, CA, 90010, US

(21) Appl. No.: 12/279,044

(22) PCT Filed: Feb. 7, 2007
(86) PCT No.: PCT/KR07/00643

§ 371 Date: Aug. 11, 2008

(30) Foreign Application Priority Data
Feb. 13, 2006 (KR) 10-2006-0013457

(51) Int. Cl. B29D 11/00; G03F 7/20; H01B 13/00

(52) U.S. Cl. 430/311; 216/13

(57) ABSTRACT

Provided is a method of manufacturing image sensor capable of maximizing light condensing efficiency so that the light input through a micro-lens is condensed onto a light receiving element. According to the present invention, inner micro-lenses or a condensing efficiency of the light input through the micro-lens. Therefore, light condensing efficiency of the light condensed onto the light receiving element in the image sensor can be improved.

### TECHNICAL FIELD

The present invention relates to a method of manufacturing an image sensor, and more particularly, to a method of manufacturing an image sensor capable of increasing light condensing efficiency of a lens.

### BACKGROUND ART

An image sensor serves to convert an optical image into an electrical signal. In general, a charge coupled device (CCD) image sensor and a complementary metal oxide semiconductor (CMOS) image sensor are widely used. In the CCD image sensor, MOS capacitors are disposed closely. Electric charges are stored in the capacitors, and the stored electric charges are moved. In the CMOS image sensor, a switching method is used. CMOS technology is used to produce MOS transistors corresponding to the number of pixels, and outputs are sequentially detected by using the MOS transistors.

In the manufacture of such image sensors, techniques for improving a photo sensitivity of an image sensor have been developed. As an example of the techniques, there is a light condensing technology. For example, the CMOS image sensor includes a light detection unit which detects light and a logic circuit unit which converts the detected light into an electrical signal to generate data.

In order to improve the photo sensitivity, it is preferable that a fill factor is increased. The fill factor denotes an occupying rate of an area of the light detection unit to the whole area of the image sensor. The logic circuit unit cannot be fundamentally removed in the image sensor. Therefore, there is a limitation to an increase in the fill factor under the limited area. Accordingly, in order to improve the photo sensitivity, the light condensing technology in which a path of light input into a region other than the light detection unit is changed to condense the light onto the light detection unit have been actively researched.

Conventionally, convex micro-lenses made of a material having a high light transmissivity are disposed on the light detection unit. Accordingly, a larger quantity of light can be transmitted to the light detection unit by refracting a path of incident light by the micro-lenses. The light input in parallel to an optical axis of the micro-lens is refracted by the micro-lens, so that a focus is formed at a certain position of the optical axis.

FIG. 1 is a vertical sectional view showing a conventional image sensor having micro-lenses.

In FIG. 1, only main components associated with light condensing in a CMOS image sensor are illustrated.

Photodiodes 12 as light receiving elements and peripheral circuits 11 for processing information on the light detected from the photodiodes 12 are disposed on a semiconductor substrate 10. An interlayer dielectric layer (sometimes, referred to as an interlayer insulator) 13 is formed over the whole structure including the photodiodes 12 and the peripheral circuits 11, and a planarization process is performed. Metal wiring layers 14 and 16 constituting unit pixels are formed on the interlayer dielectric layer 13. The metal wiring layers 14 and 16 are disposed so as not to prevent incidence of light to the photodiodes 12. Interlayer dielectric layers 15 and 17 are formed on the metal wiring layers 14 and 16 respectively. In order to protect the element against moisture or a scratch, a dielectric layer 18 constructed with an oxide film or a nitride film is formed on an upper interlayer dielectric layer 17, so that a general CMOS process is finished.

Three types of color filters 19 for implementing a color image are formed on the dielectric layer 18. Generally, a dyed photoresist is used as the color filters 19. After forming the color filters 19, an over-coating layer 20 is deposited on the color filters 19, and a planarization process is performed. Micro-lenses 21 are formed on the planarized over-coating layer 20

As described above, each of the unit pixels of the image sensor includes not only the photodiode for detecting light but also the circuit for processing a signal detected from the photodiode. Therefore, the area which the logic circuit occupies in the unit pixel causes a significant limitation in maximizing the area of the photodiode in the unit pixel having a certain area. The micro-lenses are formed over the unit pixel, so that the light input into the region other than the photodiode among the light input into the unit pixel is condensed onto the photodiode. Accordingly, light receiving efficiency of the element can be improved.

However, as a size of the unit pixel becomes smaller, a height of the upper structure becomes larger due to the interlayer dielectric layers 15 and 17 and the metal wiring layers 14 and 16 formed over the photodiodes 12. Therefore, in a conventional method of forming color filters on the unit pixel and forming a micro-lens on the color filter, a planarization layer having a certain thickness is needed to implement the micro-lenses in the process. As a result, the process becomes complicated, and the thickness of the structure is highly increased.

FIG. 2 shows a distribution of an intensity of the light incident to a photodiode according to a distance H between a center of the photodiode and a center of the micro-lens.

FIG. 3 shows an example where the light input through the micro-lens is condensed onto the photodiode.

FIG. 4 shows another example where the light input through the micro-lens is condensed onto the photodiode.

Referring to FIG. 2, the distance H between the center of the photodiode and the center of the micro-lens generally corresponds to several times a length 2Δ of one side of the photodiode. Referring to FIG. 3, it is difficult to manufacture the micro-lens of which a focus can be adjusted on the photodiode. In addition, the distance H between the center of the photodiode and the center of the micro-lens is much longer than the focal distance of the micro-lens. Thus, the light refracted by the micro-lens cannot be incident to the photodiode, and the light may be lost. Referring to FIG. 4, when light is incident at a slanted angle to the optical axis of the micro-lens, the light may not be condensed onto the photodiode according to the angle of the light.

### DISCLOSURE OF INVENTION

### Technical Problem

The present invention provides a method of manufacturing an image sensor capable of decreasing the loss of light according to a distance between a micro-lens and a photodiode and the loss of light due to light incident at a slanted angle using inner micro-lenses or a U-shaped nitride film to improve light receiving efficiency.

### Technical Solution

According to an aspect of the present invention, there is provided a method of manufacturing an image sensor comprising steps of: (a) forming a metal wiring layer on a substrate on which photodiodes and associated elements are formed; (b) forming inner micro-lenses on the metal wiring layer; (c) forming a dielectric layer on the inner micro-lenses; and (d) forming a color filter array, an over-coating layer, and micro-lenses on the dielectric layer.

According to another aspect of the present invention, there is provided a method of manufacturing an image sensor comprising steps of: (a) forming a metal wiring layer on a substrate on which photodiodes and associated elements are formed; (b) etching regions of the metal wiring layer corresponding to the photodiodes down the lower portion of the U-shape metal wiring layer, and forming a nitride film in a pre-determined thickness; (c) forming a color filter array, an over-coating layer, and micro-lenses on the nitride film.

According to still another aspect of the present invention, there is provided a method of manufacturing an image sensor comprising steps of: (a) forming a metal wiring layer on a substrate on which photodiodes and associated elements are formed; (b) etching regions of the metal wiring layer corresponding to the photodiodes down the lower portion of the U-shape metal wiring layer, and forming a nitride film having a predetermined thickness; (c) forming inner micro-lenses on the nitride film; (d) forming a dielectric layer on the inner micro-lenses; and (e) forming a color filter array, an over-coating layer, and micro-lenses on the dielectric layer.

### BRIEF DESCRIPTION OF THE DRAWINGS

FIG. 1 is a vertical sectional view showing a conventional image sensor having micro-lenses;

FIG. 2 shows a distribution of an intensity of the light incident to a photodiode according to a distance H between a center of the photodiode and a center of the micro-lens;

FIG. 3 shows an example where the light input through the micro-lens is condensed onto the photodiode;

FIG. 4 shows another example where the light input through the micro-lens is condensed onto the photodiode;

FIG. 5 is a vertical sectional view showing an image sensor manufactured by a method of manufacturing an image sensor according to an embodiment of the present invention;

FIGS. 6 to 14 are sectional views showing a process of forming inner micro-lenses in the image sensor;

FIG. 15 is a vertical sectional view showing an image sensor manufactured by a method of manufacturing an image sensor according to another embodiment of the present invention; and

FIG. 16 is a vertical sectional view showing an image sensor manufactured by a method of manufacturing an image sensor according to another embodiment of the present invention.

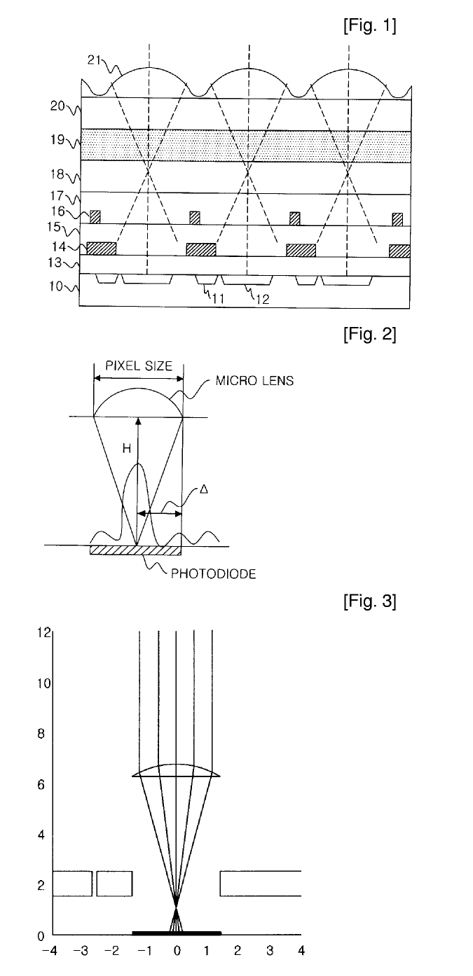

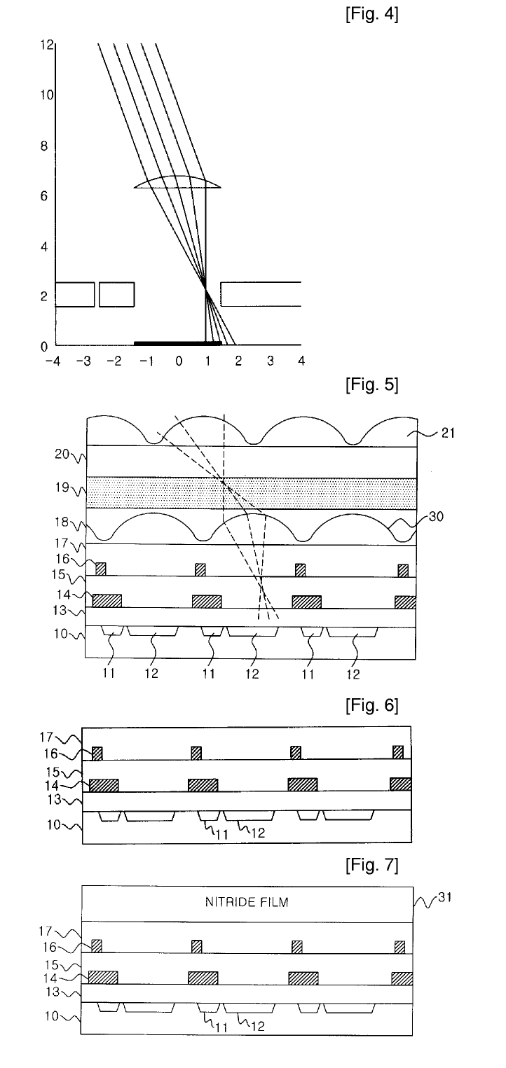

### BEST MODE FOR CARRYING OUT THE INVENTION

Hereinafter, exemplary embodiments of the present invention will be described in detail with reference to the attached drawings.

FIG. 5 is a vertical sectional view showing an image sensor manufactured by a method of manufacturing an image sensor according to an embodiment of the present invention.

Referring to FIG. 5, the image sensor is provided with inner micro-lenses. Now, layers in the image sensor will be described.

photodiodes 12 as light receiving elements and peripheral circuits 11 for processing information on the light detected from the photodiodes 12 are disposed on a wafer substrate 10. Metal wiring layers 14 and 16 are formed thereon.

Inner micro-lenses 30, a dielectric layer 18, a color filter array 19, and an over-coating layer 20 are formed successively on the metal wiring layers 14 and 16. The over-coating layer 20 functions to planarize steps caused by the color filter array 19 and to adjust a focal distance. Micro-lenses 21 for condensing light are formed on the over-coating layer 20 so that the micro-lens 21 corresponds to the each of color filters of color filter array 19

In the image sensor manufactured by a method of manufacturing an image sensor according to an embodiment of the present invention shown in FIG. 5, in order to condense the light input at a slanted angle from the micro-lens 21 onto the photodiode 12 as the light receiving element, each of the inner micro-lenses 30 is formed between the metal wiring layer 16 and the dielectric layer 18. Therefore, light condensing efficiency can be increased.

FIGS. 6 to 14 are sectional views showing a process of forming the inner micro-lenses in the image sensor.

Referring to FIG. 6, the photodiodes 12 and the peripheral circuits 11 are formed on the substrate 10. Interlayer dielectric layers 15 and 17 and the metal wiring layers 14 and 16 are formed thereon.

Referring to FIG. 7, a nitride film 31 is formed on the interlayer dielectric layer 17 formed on the metal wiring layer 16.

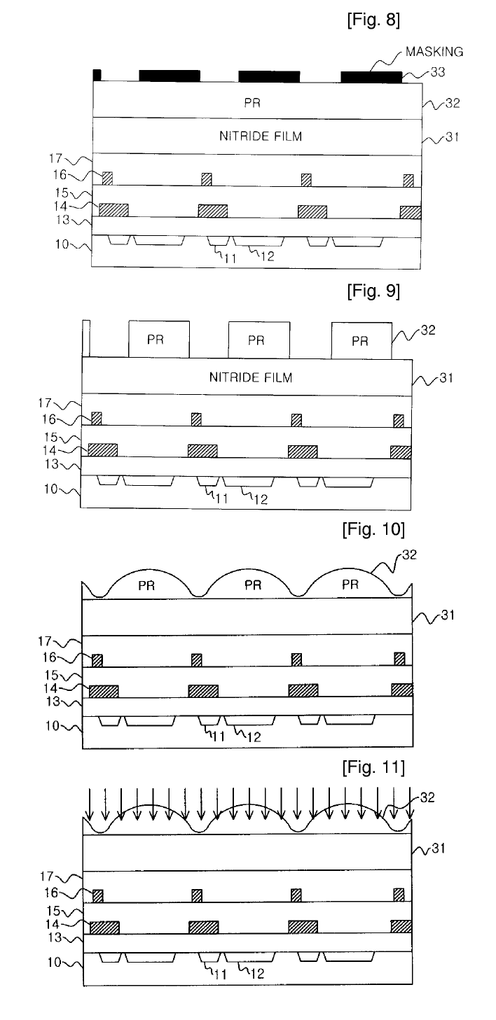

Referring to FIG. 8, a photoresist layer 32 used for forming the inner micro-lenses 30 is formed, and a mask 33 operation is performed on regions of the photoresist layer 32 corresponding to the photodiodes 12. Since the inner micro-lenses 30 are formed on the regions of the photoresist layer 32 corresponding to the photodiodes 12 by the photoresist, the mask operation is performed so as not to remove regions where the inner micro-lenses 30 are to be formed during an etching process of the photoresist.

Referring to FIG. 9, the regions of the photoresist layer which the mask is not formed are removed.

Referring to FIG. 10, a heat treatment is performed on the regions of photoresist layer which are not removed, so that the semi-spherical photo resists are formed.

FIG. 11 is a sectional view showing a process of etching the semi-spherical photo resists. Referring to FIG. 11, in the etching process of the semi-spherical photoresists, the etching process is also performed on the nitride film under the photoresists, so that the etched nitride film has a semi-spherical form.

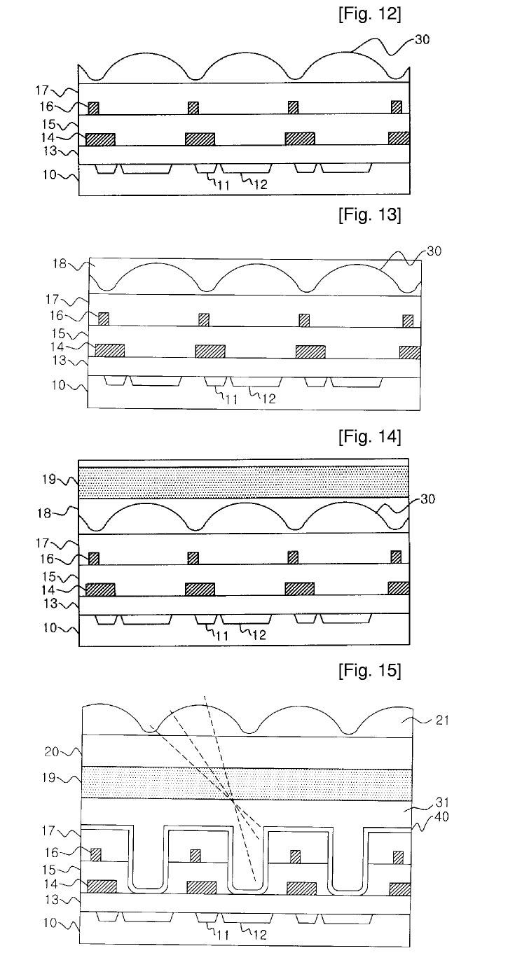

FIG. 12 is a sectional view showing a semi-spherical nitride film 31 formed by etching. Referring to FIG. 12, the semi-spherical nitride film 31 becomes each of the inner micro-lenses 30. Before the nitride film has a semi-spherical form, the nitride film is represented by reference numeral 31. After the nitride film has a semi-spherical form, the nitride film, that is, the inner micro-lens is represented by reference numeral 30.

FIGS. 13 and 14 are sectional views showing a process of forming the dielectric layer 18 and the color filter array 19 over the inner micro-lenses 30.

FIG. 15 is a vertical sectional view showing an image sensor manufactured by a method of manufacturing an image sensor according to another embodiment of the present invention.

Referring to FIG. 15, the image sensor is manufactured by etching the interlayer dielectric layers 15 and 17 and the metal wiring layers in a U-shaped form and forming a nitride film 31, a color filter array 19, an over-coating layer 20, and a micro-lens 21 thereon. The nitride film 31 is formed to condense the light incident to a high refractive portion of the micro-lens on the photodiode 12. The nitride film 31 which fills the etched U-shaped portions functions as the reflection layer for condensing light by totally reflecting the incident light.

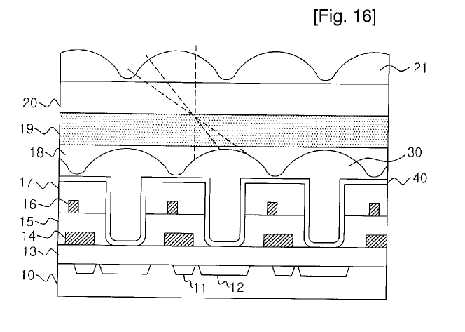

FIG. 16 is a vertical sectional view showing an image sensor manufactured by a method of manufacturing an image sensor according to still another embodiment of the present invention.

Referring to FIG. 16, a metal wiring layer etched in a U-shaped form and inner micro-lenses are formed in the image sensor.

In order to condense the light incident to a high refractive portion of the micro-lens 21 onto the photodiode 12, regions of the metal wiring layer corresponding to the photodiode 12 are etched down the lower portion of the U-shaped metal wiring layer. Thus, a nitride film having a predetermined thickness is formed.

The nitride film 31 having the predetermined thickness which fills the etched U-shaped metal wiring layers 14 and 16 functions as the reflection layer for condensing the light by totally reflecting the incident light.

Moreover, the nitride film is etched in a semi-spherical form to form the inner micro-lenses 30. The process of forming the inner micro-lenses 30 is the same as that shown in FIGS. 6 to 12. A dielectric layer 18, a color filter array 19, an over-coating layer 20, and a micro-lens 21 are formed on the inner micro-lens 30.

As described above, the image sensor shown in FIG. 16 is a combination of the image sensor shown in FIG. 5 and the image sensor shown in FIG. 15. Accordingly, light condensing efficiency can be maximized.

While the present invention has been particularly shown and described with reference to exemplary embodiments thereof, it will be understood by those skilled in the art that various changes in form and details may be made therein without departing from the spirit and scope of the present invention as defined by the appended claims.

### INDUSTRIAL APPLICABILITY

According to the present invention, inner micro-lenses or a U-shaped nitride film are used to maximize light condensing efficiency of the light input through the micro-lens. Therefore, light condensing efficiency of the light condensed onto the light receiving element in the image sensor can be improved.

1. A method of manufacturing an image sensor comprising steps of:
(a) forming a metal wiring layer on a substrate;
(b) forming inner micro-lenses on the metal wiring layer;
(c) forming a dielectric layer over the inner micro-lenses; and
(d) forming a color filter array, an over-coating layer, and micro-lenses on the dielectric layer.

2. The method according to claim 1, wherein the step of forming the inner micro-lenses comprises steps of:
(b1) forming a nitride film and a photoresist layer on the metal wiring layer;
(b2) performing a mask operation on regions of the photoresist layer cor-responding to the photodiodes;
(b3) removing regions of the photoresist layer which do not correspond to the photodiodes, and performing a heat treatment on the regions of the photoresist layer which are not removed so as to form semi-spherical photoresists; and
(b4) etching the semi-spherical photoresists and the nitride film placed under the photoresists so as to form semi-spherical nitride lenses.

3. A method of manufacturing an image sensor comprising steps of:
(a) forming a metal wiring layer on a substrate;
(b) etching regions of the metal wiring layer corresponding to the photodiodes down the lower portion of the U-shape metal wiring layer, and forming a nitride film having a predetermined thickness; and
(c) forming a color filter array, an over-coating layer, and micro-lenses on the nitride film.

4. A method of manufacturing an image sensor comprising steps of:
(a) forming a metal wiring layer on a substrate on which photodiodes and associated elements are formed;
(b) etching regions of the metal wiring layer corresponding to the photodiodes down the lower portion of the U-shape metal wiring layer, and forming a nitride film having a predetermined thickness;
(c) forming inner micro-lenses on the nitride film;
(d) forming a dielectric layer on the inner micro-lenses; and
(e) forming a color filter array, an over-coating layer, and micro-lenses on the dielectric layer.
